(19) United States
(12) Patent Application Publication
(10) Pub. No.: US 2021/0375226 A1
(43) Pub. Date: Dec. 2, 2021

(54) DISPLAY DEVICE

(71) Applicant: SHARP KABUSHIKI KAISHA, Osaka (JP)

(72) Inventors: TOSHIAKI FUJIHARA, Osaka (JP); KIMIHIRO ARAI, Osaka (JP)

(21) Appl. No.: 17/232,661

(22) Filed: Apr. 16, 2021

Related U.S. Application Data
(60) Provisional application No. 63/032,007, filed on May 29, 2020.

(51) Int. Cl. G09G 3/36; G11C 19/28; H02H 9/04

(52) U.S. Cl. CPC G09G 3/3674; G09G 3/3648; G11C 19/28; G02F 1/13454; G09G 2310/08; G09G 2310/0286; G09G 3/3685; H02H 9/045

(57) ABSTRACT

A shift register configured of a plurality of unit circuits constituting a monolithic gate driver is applied with a gate start pulse signal that allows vertical scanning to start and a clear signal that allows a state of each of the plurality of unit circuits to be initialized after an end of the vertical scanning. The gate start pulse signal and the clear signal are set in such a manner that at least one of the gate start pulse signal and the clear signal is at an off level at any point of time. A resistor is provided on at least one of a wiring line for the gate start pulse signal and a wiring line for the clear signal.

### CROSS-REFERENCE TO RELATED APPLICATIONS

This application claims the benefit of priority to U.S. Provisional Application No. 63/032,007 filed on May 29, 2020. The entire contents of the above-identified application are hereby incorporated by reference.

### BACKGROUND

### Technical Field

The disclosure relates to a display device including a monolithic gate driver (scanning signal line drive circuit).

In the related art, a liquid crystal display device that includes a display portion including a plurality of source bus lines (video signal lines) and a plurality of gate bus lines (scanning signal lines) is known. In such a liquid crystal display device, pixel forming sections each of which forms a pixel are provided at intersections of the source bus lines and the gate bus lines. Each pixel forming section includes a thin film transistor (pixel TFT) that is a switching element with a gate terminal connected to a gate bus line passing through a corresponding intersection and a source terminal connected to a source bus line passing through the intersection, a pixel capacitance configured to hold a pixel voltage value, and the like. The liquid crystal display device also includes a gate driver (a scanning signal line drive circuit) for driving the gate bus lines and a source driver (a video signal line drive circuit) for driving the source bus lines.

A video signal indicating a pixel voltage value is transmitted through the source bus lines. However, each source bus line is incapable of transmitting video signals indicating pixel voltage values for a plurality of rows at one time (at the same time). Thus, video signals are sequentially written (charged) into pixel capacitances in a plurality of pixel forming sections provided in the display portion on a row-by-row basis. Thus, the gate driver is configured of a shift register having a plurality of stages to sequentially select a plurality of gate bus lines for each predetermined period. Then, active scanning signals (scanning signals at a voltage level that causes the pixel TFT to be in an on state) are sequentially output from the respective stages of the shift register to allow the video signals to be sequentially written into the pixel capacitances on a row-by-row basis as described above. Note that, in the present specification, a circuit constituting each of stages of a shift register is referred to as a “unit circuit”.

In the related art, a gate driver is often mounted at a periphery of a substrate constituting a liquid crystal panel, as an Integrated Circuit (IC) chip. However, in recent years, liquid crystal display devices having a configuration in which the gate driver is formed directly on a substrate gradually increase. Such a gate driver is referred to as a “GDM circuit”, a “monolithic gate driver” or the like.

However, circuit elements such as transistors constituting the GDM circuit may be destroyed due to electro-static discharge (ESD). Thus, a protection circuit may be provided that includes a diode ring configured of two diode elements between an input terminal for a GDM control signal that controls an operation of the GDM circuit (an input terminal on a substrate configuring a liquid crystal panel) and the GDM circuit. With relation to a liquid crystal display device provided with such a protection circuit, JP 2019-184938 A discloses an invention for preventing degradation of display quality caused by breakage or a characteristic shift of a diode element in the protection circuit.

According to the protection circuit described above, the breakage of the circuit element caused by an extremely high voltage due to ESD being applied to the GDM circuit is suppressed. However, in a case where two GDM control signals that are set not to be at an on level at the same time are used, the circuit elements in the GDM circuit may be destroyed when the two GDM control signals are at the on level due to malfunction or ESD. A case in which an n-channel type thin film transistor is used will be exemplified and described below.

As illustrated in FIG. 12, a GDM circuit is configured of a shift register 910 including a plurality of unit circuits 9. A GDM control signal to be used includes a gate start pulse signal GSP for starting vertical scanning in which a plurality of gate bus lines are sequentially brought into a selected state, a clear signal CLR for initializing a state of each unit circuit 9 after an end of the vertical scanning, a gate clock signal (not illustrated in FIG. 12) for transferring a shift pulse, and the like. The gate start pulse signal GSP is applied to one or a plurality of unit circuits 9 on a first stage side of the shift register 910, and the clear signal CLR and the gate clock signal are applied to all of the unit circuits 9. A scanning signal Gout for being applied to the corresponding gate bus line is output from each unit circuit 9.

FIG. 13 is a circuit diagram illustrating a configuration of a part of the unit circuit 9. Note that here, the unit circuit 9(1) at a first stage is focused on. Furthermore, various configurations have been adopted for a circuit configuration in a portion denoted by a reference sign of 91, and are not particularly limited. As illustrated in FIG. 13, two thin film transistors T1 and T2 are included in the unit circuit 9. The gate start pulse signal GSP is applied to a gate terminal and a drain terminal of the thin film transistor T1, and a source terminal is connected to an output control node. For the thin film transistor T2, the clear signal CLR is applied to a gate terminal, a drain terminal is connected to the output control node, and a power supply voltage VSS of a low level is applied to a source terminal.

FIG. 14 illustrates waveforms of the gate start pulse signal GSP and the clear signal CLR. Note that Vgh is a voltage (gate high voltage) of a level that allows a pixel TFT to be in an on state, and Vgl is a voltage (gate low voltage) of a level that allows the pixel TFT to be in an off state. The gate start pulse signal GSP is maintained at the high level (on level) only for a part of a period immediately after the start of each vertical scanning period, and is maintained at the low level (off level) for the other period. The clear signal CLR is maintained at the high level (on level) only for a part of a period near the end of each vertical scanning period, and is maintained at the low level (off level) for the other periods. In this way, the gate start pulse signal GSP and the clear signal CLR are set not to be at the high level (on level) at the same time. In other words, at any point of time, at least one of the gate start pulse signal GSP and the clear signal CLR is at the low level (off level).

Under the preconditions as described above, for example, the clear signal CLR may also be at the high level, as illustrated in a portion denoted by a reference sign of 92 in FIG. 15, due to malfunction or ESD in a period for which the gate start pulse signal GSP is at the high level. In such a case, in the unit circuit 9 (see FIG. 13), the thin film transistor T1 is brought into the on state by the gate start pulse signal GSP being at the high level, and the thin film transistor T2 is brought into the on state by the clear signal CLR being at the high level. In other words, both of the thin film transistor T1 and the thin film transistor T2 are set to the on state. As a result, a through current flows into the unit circuit 9 as indicated by an arrow denoted by a reference sign of 93 in FIG. 16. An overcurrent, such as the through current, causes breakage of the thin film transistors T1 and T2 (for example, breakage due to the semiconductor layer being melted). When the circuit elements in the GDM circuit are destroyed in the manner described above, display failure such as lighting failure occurs.

Note that, according to a configuration in which a protection circuit including a diode ring is provided (for example, the configuration disclosed in JP 2019-184938 A), it is possible to prevent an extremely high voltage due to ESD from being applied to a GDM circuit, but it is not possible to prevent two GDM control signals that are set not to be at an on level at the same time from being at the on level at the same time.

### SUMMARY

Therefore, an object of the following disclosure is to achieve a display device in which the generation of an overcurrent in a GDM circuit (a monolithic scanning signal line drive circuit) due to malfunction or ESD can be prevented.

(1) A display device according to some embodiments of the disclosure is a display device including a display portion including a plurality of scanning signal lines, a scanning signal line drive circuit configured to drive the plurality of scanning signal lines, and a timing control circuit configured to generate a first control signal and a second control signal configured to control an operation of the scanning signal line drive circuit, wherein the plurality of scanning signal lines and the scanning signal line drive circuit are formed on a panel substrate that is the same as a panel substrate configuring the display portion, the timing control circuit generates the first control signal and the second control signal in such a manner that at least one of the first control signal and the second control signal is at an off level at any point of time, the first control signal and the second control signal are each supplied to the scanning signal line drive circuit from the timing control circuit through a first control signal wiring line and a second control signal wiring line disposed on the panel substrate, and a resistor is provided on at least one of the first control signal wiring line and the second control signal wiring line.

According to such a configuration, in the display device including the monolithic scanning signal line drive circuit, the first control signal and the second control signal are generated in such a manner that at least one of the first control signal and the second control signal is at the off level at any point of time. The first control signal is supplied to the scanning signal line drive circuit through the first control signal wiring line disposed on the panel substrate, and the second control signal is supplied to the scanning signal line drive circuit through the second control signal wiring line disposed on the panel substrate. Here, the resistor is provided on at least one of the first control signal wiring line and the second control signal wiring line. Thus, even when a through current flows into the scanning signal line drive circuit due to both the first control signal and the second control signal being at an on level because of the occurrence of malfunction or ESD, a current value of the through current is prevented from becoming significantly large. In this way, the generation of an overcurrent is prevented. As described above, the display device in which the occurrence of an overcurrent due to malfunction or ESD (an overcurrent in a monolithic scanning signal line drive circuit) can be prevented is achieved.

(2) Further, the display device according to some embodiments of the disclosure includes the configuration of (1) described above, wherein the scanning signal line drive circuit is configured of a shift register including a plurality of unit circuits corresponding one-to-one to the plurality of scanning signal lines, the first control signal is a vertical scanning start signal to be applied to a unit circuit at least at a first stage among the plurality of unit circuits to allow vertical scanning in which the plurality of scanning signal lines are sequentially brought into a selected state to start, and the second control signal is a clear signal to be applied to the plurality of unit circuits to allow a state of the plurality of unit circuits to be initialized after an end of the vertical scanning.

(3) Further, the display device according to some embodiments of the disclosure includes the configuration of (2) described above, wherein the resistor is provided only on the first control signal wiring line.

(4) Further, the display device according to some embodiments of the disclosure includes the configuration of (2) described above, wherein the resistor is provided only on the second control signal wiring line.

(5) Further, the display device according to some embodiments of the disclosure includes the configuration (2) described above, wherein the resistor is provided on each of the first control signal wiring line and the second control signal wiring line.

(6) Further, the display device according to some embodiments of the disclosure includes the configuration of (2) described above, wherein a plurality of clock signals are further supplied from the timing control circuit to the scanning signal line drive circuit, each of the plurality of unit circuits includes an output node connected to a corresponding scanning signal line among the plurality of the scanning signal lines, an output control transistor including a control terminal, a first conduction terminal to be applied with one of the plurality of clock signals, and a second conduction terminal connected to the output node, an output control node connected to the control terminal of the output control transistor, a set transistor including a control terminal to be applied with a set signal, a first conduction terminal to be applied with the set signal or a power supply voltage of an on level, and a second conduction terminal connected to the output control node, and an initialization transistor including a control terminal connected to the second control signal wiring line, a first conduction terminal connected to the output control node, and a second conduction terminal to be applied with a power supply voltage of an off level, and the unit circuit at least at the first stage among the plurality of unit circuits is applied with the vertical scanning start signal as the set signal.

(7) Further, a display device according to some embodiments of the disclosure is a display device including a display portion including a plurality of scanning signal lines, a scanning signal line drive circuit configured to drive the plurality of scanning signal lines, and a timing control circuit configured to generate a first control signal, a second control signal, and a plurality of clock signals configured to control an operation of the scanning signal line drive circuit, wherein the plurality of scanning signal lines and the scanning signal line drive circuit are formed on a panel substrate that is the same as a panel substrate configuring the display portion, the timing control circuit generates the first control signal and the second control signal in such a manner that at least one of the first control signal and the second control signal is at an off level at any point of time, the first control signal, the second control signal, and the plurality of clock signals are each supplied to the scanning signal line drive circuit from the timing control circuit through a first control signal wiring line, a second control signal wiring line, and a plurality of clock signal wiring lines disposed on the panel substrate, and a wiring line resistance of at least one of the first control signal wiring line and the second control signal wiring line is greater than a wiring line resistance of the plurality of clock signal wiring lines.

According to such a configuration, in the display device including the monolithic scanning signal line drive circuit, the first control signal and the second control signal are generated in such a manner that at least one of the first control signal and the second control signal is at the off level at any point of time. The first control signal is supplied to the scanning signal line drive circuit through the first control signal wiring line disposed on the panel substrate, and the second control signal is supplied to the scanning signal line drive circuit through the second control signal wiring line disposed on the panel substrate. In addition, the clock signals are supplied to the scanning signal line drive circuit through the clock signal wiring lines. Here, the wiring line resistance of the at least one of the first control signal wiring line and the second control signal wiring line is greater than the wiring line resistance of the clock signal wiring lines. Thus, even when a through current flows into the scanning signal line drive circuit due to both the first control signal and the second control signal being at an on level because of the occurrence of malfunction or ESD, a current value of the through current is prevented from becoming significantly large. In this way, the generation of an overcurrent is prevented. As described above, the display device in which the occurrence of an overcurrent due to malfunction or ESD (an overcurrent in a monolithic scanning signal line drive circuit) can be prevented is achieved.

(8) Further, the display device according to some embodiments of the disclosure includes the configuration of (7) described above, wherein the scanning signal line drive circuit is configured of a shift register including a plurality of unit circuits corresponding one-to-one to the plurality of scanning signal lines, the first control signal is a vertical scanning start signal to be applied to a unit circuit at least at a first stage among the plurality of unit circuits to allow vertical scanning in which the plurality of scanning signal lines are sequentially brought into a selected state to start, and the second control signal is a clear signal to be applied to the plurality of unit circuits to allow a state of the plurality of unit circuits to be initialized after an end of the vertical scanning.

(9) Further, the display device according to some embodiments of the disclosure includes the configuration of (8) described above, wherein each of the plurality of unit circuits includes an output node connected to a corresponding scanning signal line among the plurality of the scanning signal lines, an output control transistor including a control terminal, a first conduction terminal to be applied with one of the plurality of clock signals, and a second conduction terminal connected to the output node, an output control node connected to the control terminal of the output control transistor, a set transistor including a control terminal to be applied with a set signal, a first conduction terminal to be applied with the set signal or a power supply voltage of an on level, and a second conduction terminal connected to the output control node, and an initialization transistor including a control terminal connected to the second control signal wiring line, a first conduction terminal connected to the output control node, and a second conduction terminal to be applied with a power supply voltage of an off level, and the unit circuit at least at the first stage among the plurality of unit circuits is applied with the vertical scanning start signal as the set signal.

(10) Further, the display device according to some embodiments of the disclosure includes the configuration of (7) described above, wherein the at least one of the first control signal wiring line and the second control signal wiring line is formed of a material having resistivity greater than resistivity of the plurality of clock signal wiring lines.

(11) Further, the display device according to some embodiments of the disclosure includes the configuration of (7) described above, wherein a material of the at least one of the first control signal wiring line and the second control signal wiring line is indium tin oxide.

These and other objects, features, aspects, and advantages of the disclosure will become more apparent from the following detailed description of the disclosure with reference to the accompanying drawings.

### BRIEF DESCRIPTION OF DRAWINGS

The disclosure will be described with reference to the accompanying drawings, wherein like numbers reference like elements.

FIG. 1 is a diagram for describing a configuration that prevents an overcurrent in a GDM circuit from being generated in a first embodiment.

FIG. 2 is a block diagram illustrating an overall configuration of a liquid crystal display device according to the first embodiment.

FIG. 3 is a circuit diagram illustrating a configuration of a pixel forming section in the first embodiment.

FIG. 4 is a block diagram for describing a schematic configuration of a gate driver in the first embodiment.

FIG. 5 is a block diagram illustrating a configuration example of a shift register in the first embodiment.

FIG. 6 is a circuit diagram illustrating a configuration example of a unit circuit in the first embodiment.

FIG. 7 is a signal waveform diagram for describing an operation of the unit circuit in a normal case in the first embodiment.

FIG. 8 is a signal waveform diagram for describing an overall operation of the gate driver in the first embodiment.

FIG. 9 is a diagram for describing a configuration that prevents an overcurrent in a GDM circuit from being generated in a second embodiment.

FIG. 10 is a signal waveform diagram for describing a reason why the generation of an overcurrent is prevented by providing a resistor on a CLR signal wiring line in the second embodiment.

FIG. 11 is a diagram for describing a configuration that prevents an overcurrent in a GDM circuit from being generated in a third embodiment.

FIG. 12 is a block diagram illustrating a schematic configuration of a GDM circuit in relation to a known example.

FIG. 13 is a circuit diagram illustrating a configuration of a part of a unit circuit in relation to the known example.

FIG. 14 is a waveform diagram of a gate start pulse signal and a clear signal in a normal case in relation to the known example.

FIG. 15 is an example of a waveform diagram of a gate start pulse signal and a clear signal when malfunction or ESD occurs in relation to the known example.

FIG. 16 is a diagram for describing the occurrence of a through current in relation to the known example.

### DESCRIPTION OF EMBODIMENTS

In the following, each embodiment of the disclosure will be described with reference to the accompanying drawings. Note that each transistor is a field-effect transistor, and more specifically is an n-channel type TFT. In the following description related to the n-channel type TFT, a gate terminal corresponds to the control terminal, a drain terminal corresponds to the first conduction terminal, and a source terminal corresponds to the second conduction terminal. With regard to this, for the n-channel type transistor, one terminal having a greater electric potential of the terminals corresponding to the drain and the source is generally referred to as a drain, but in the description of the present specification, one of the terminals is defined as a drain and the other is defined as a source, and thus, a source potential may be greater than a drain potential in some cases.

### 1. First Embodiment

### 1.1 Overall Configuration and Operation Outline

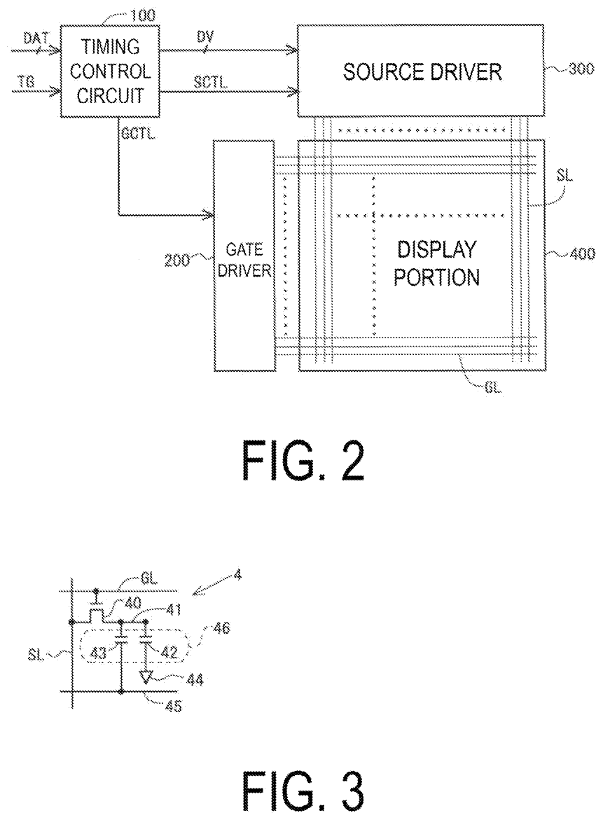

FIG. 2 is a block diagram illustrating an overall configuration of a liquid crystal display device according to a first embodiment. The liquid crystal display device includes a timing control circuit 100, a gate driver (scanning signal line drive circuit) 200, a source driver (video signal line drive circuit) 300, and a display portion 400.

The display portion 400 is disposed with a plurality of source bus lines (video signal lines) and a plurality of gate bus lines (scanning signal lines). In the display portion 400, a pixel forming section that forms a pixel is provided at each of intersections of the source bus lines and the gate bus lines. FIG. 3 is a circuit diagram illustrating a configuration of a single pixel forming section 4. Each of the pixel forming sections 4 includes a pixel thin film transistor (TFT) 40 serving as a switching element in which a gate terminal is connected to a gate bus line GL passing through a corresponding intersection and a source terminal is connected to a source bus line SL passing through the intersection, a pixel electrode 41 connected to a drain terminal of the pixel TFT 40, a common electrode 44 and an auxiliary capacitance electrode 45 provided in common to the plurality of pixel forming sections 4 formed in the display portion 400, a liquid crystal capacitance 42 formed by the pixel electrode 41 and the common electrode 44, and an auxiliary capacitance 43 formed by the pixel electrode 41 and the auxiliary capacitance electrode 45. A pixel capacitance 46 is configured of the liquid crystal capacitance 42 and the auxiliary capacitance 43. Note that the configuration of the pixel forming section 4 is not limited to the configuration illustrated in FIG. 3, and a configuration in which the auxiliary capacitance 43 and the auxiliary capacitance electrode 45 are not provided, for example, may be employed.

Incidentally, the liquid crystal panel constituting the display portion 400 is configured of two glass substrates (a TFT array substrate and a counter substrate) provided to face each other with a liquid crystal interposed therebetween. The TFT array substrate and the counter substrate are bonded together by, for example, a sealing member. The gate driver 200 is formed directly on the TFT array substrate. In addition, typically, the source bus line SL, the gate bus line GL, the pixel TFT 40, the pixel electrode 41, and the auxiliary capacitance electrode 45 are also formed on the TFT array substrate, and the common electrode 44 is formed on the counter substrate. However, the configuration is not limited thereto. Note that the source driver 300 is provided, for example, by a chip on film (COF) method (that is, provided in a form of an IC chip on a flexible printed circuit (FPC) connected to the TFT array substrate), and the timing control circuit 100 is provided on a printed circuit board connected to the TFT array substrate via the FPC, for example. As described above, the gate bus lines GL and the gate driver 200 are formed on the same panel substrate (the TFT array substrate). In other words, the gate driver 200 in the present embodiment is a GDM circuit.

The timing control circuit 100 receives image data DAT and a group of timing signals TG such as a horizontal synchronization signal and a vertical synchronization signal transmitted from the outside, and outputs a digital video signal DV, a gate control signal (GDM control signal) GCTL for controlling an operation of the gate driver 200, and a source control signal SCTL for controlling an operation of the source driver 300. The gate control signal GCTL includes a gate start pulse signal, a gate clock signal, and a clear signal. The source control signal SCTL includes a source start pulse signal, a source clock signal, and a latch strobe signal. Note that a vertical scanning start signal is achieved by the gate start pulse signal.

The gate driver 200 repeats application of an active scanning signal to each gate bus line GL with one vertical scanning period being as a cycle, based on the gate control signal GCTL transmitted from the timing control circuit 100. Note that the gate driver 200 will be described below in detail.

The source driver 300 outputs a drive video signal to the plurality of source bus lines SL on the basis of the digital video signal DV and the source control signal SCTL transmitted from the timing control circuit 100. At this time, the source driver 300 sequentially holds the digital video signal DV indicating a voltage to be applied to each of the source bus lines SL at a timing when a pulse of the source clock signal is generated. Then, at a timing when a pulse of the latch strobe signal is generated, the held digital video signal DV is converted into an analog voltage. The converted analog voltage is concurrently applied (outputted) to all of the source bus lines SL as the drive video signal.

As described above, the scanning signal is applied to the gate bus lines GL, and the drive video signal is applied to the source bus lines SL, and, as a result, an image corresponding to the image data DAT transmitted from the outside is displayed on the display portion 400.

### 1.2 Gate Driver

The gate driver 200 in the present embodiment will be described below in detail.

### 1.2.1 Configuration

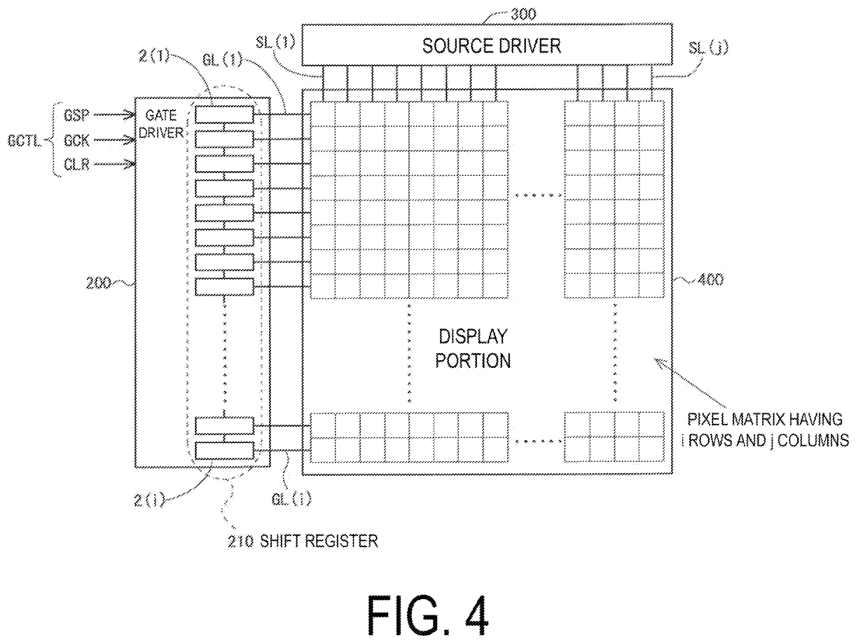

FIG. 4 is a block diagram for describing a schematic configuration of the gate driver 200. The gate driver 200 includes a shift register 210 including a plurality of stages (a plurality of unit circuits 2). The display portion 400 has a pixel matrix having i rows and j columns, and the respective stages of the shift register 210 are provided corresponding one-to-one to the respective rows of the pixel matrix.

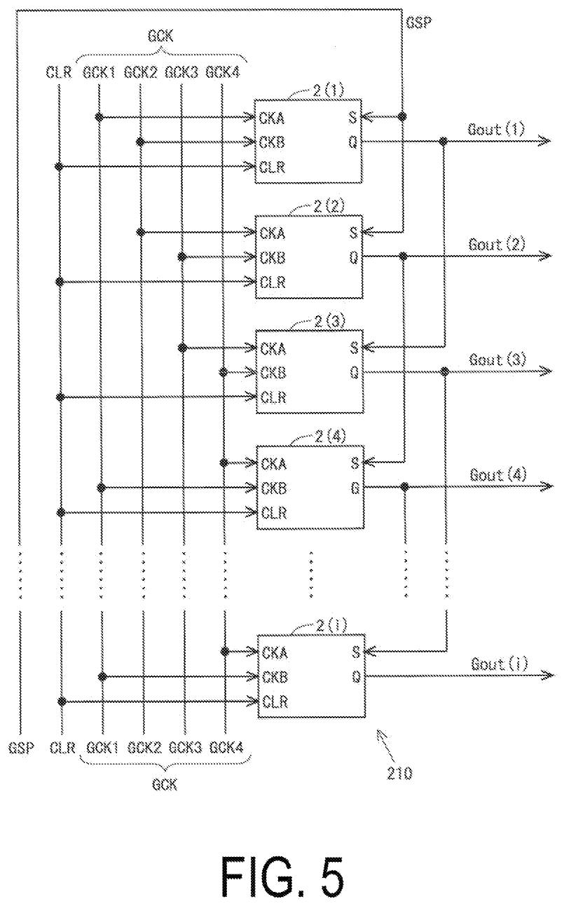

FIG. 5 is a block diagram illustrating a configuration example of the shift register 210. The shift register 210 is applied with the gate start pulse signal GSP, the gate clock signal GCK, and the clear signal CLR as the gate control signal (GDM control signal) GCTL. In the present embodiment, the gate clock signal GCK is configured of a four-phase clock signal (from a first gate clock signal GCK1 to a fourth gate clock signal GCK4). Note that in the present embodiment, the first control signal is achieved by the gate start pulse signal GSP, and the second control signal is achieved by the clear signal CLR.

Each unit circuit 2 includes an input node configured to receive a first clock signal CKA, an input node configured to receive a second clock signal CKB, an input node configured to receive the clear signal CLR, an input node configured to receive a set signal S, and an output node configured to output an output signal Q. Note that each unit circuit 2 also includes an input node configured to receive the power supply voltage VSS of a low level, but the illustration thereof is omitted in FIG. 5.

The gate clock signal GCK is applied to each stage (each unit circuit 2) of the shift register 210 as follows. The unit circuit 2(1) at the first stage is applied with the first gate clock signal GCK1 as the first clock signal CKA, and is applied with the second gate clock signal GCK2 as the second clock signal CKB. The unit circuit 2(2) at the second stage is applied with the second gate clock signal GCK2 as the first clock signal CKA, and is applied with the third gate clock signal GCK3 as the second clock signal CKB. The unit circuit 2(3) at the third stage is applied with the third gate clock signal GCK3 as the first clock signal CKA, and is applied with the fourth gate clock signal GCK4 as the second clock signal CKB. The unit circuit 2(4) at the fourth stage is applied with the fourth gate clock signal GCK4 as the first clock signal CKA, and is applied with the first gate clock signal GCK1 as the second clock signal CKB. Such a configuration is repeated for every four stages throughout all stages of the shift register 210.

In addition, the gate start pulse signal GSP is applied as the set signal S to the unit circuit 2(1) at the first stage and the unit circuit 2(2) at the second stage, and the output signal Q of the unit circuit 2(K−2) at the (K−2)-th stage is applied as the set signal S to the unit circuit 2(K) at the K-th stage, when K is an integer equal to or greater than 3 and equal to or less than i. The clear signal CLR is applied in common to all of the unit circuits 2(1) to 2(i). The power supply voltage VSS of the low level is also applied in common to all of the unit circuits 2(1) to 2(i).

Furthermore, the output signals Q of all of the unit circuits 2(1) to 2(i) are respectively applied as scanning signals Gout(1) to Gout(i) to the gate bus lines GL(1) to GL(i) from the first row to the i-th row. When k is an integer equal to or greater than 1 and equal to or less than (i−2), the output signal Q of the unit circuit 2(k) at the k-th stage is applied as the set signal S to the unit circuit 2(k+2) at the (k+2)-th stage.

Note that the configuration of the shift register 210 illustrated in FIG. 5 is merely an example, and the disclosure is not limited thereto. For example, a configuration in which the gate start pulse signal GSP is applied to only the unit circuit 2(1) at the first stage, or a configuration in which different gate start pulse signals GSP are respectively applied to the unit circuit 2(1) at the first stage and the unit circuit 2(2) at the second stage may be employed. Additionally, for example, a configuration including a unit circuit (unit circuit not connected to the gate bus line GL in the display portion 400) 2 as a so-called dummy stage, or a configuration in which a clock signal other than the four-phase clock signal is used for the gate clock signal GCK may be employed.

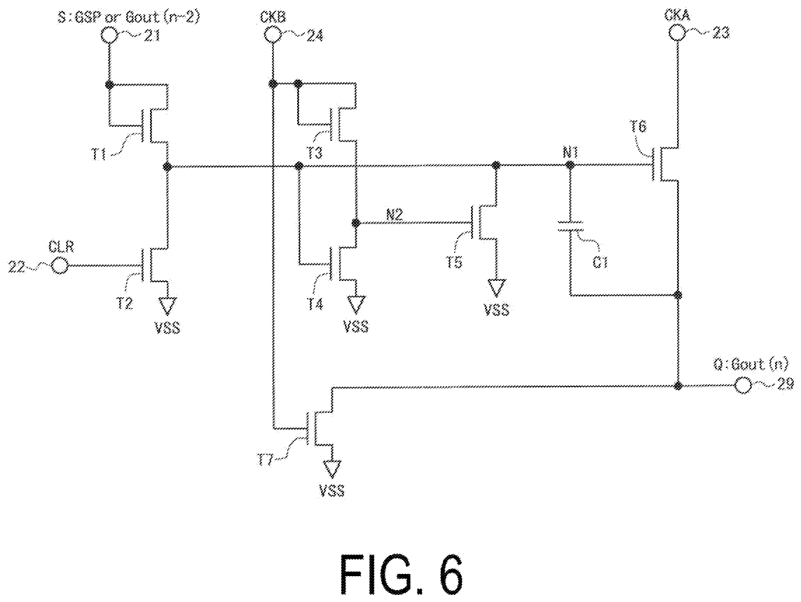

FIG. 6 is a circuit diagram illustrating a configuration example of the unit circuit 2 (assumed to be at the n-th stage) in the present embodiment. As illustrated in FIG. 6, the unit circuit 2 includes seven thin film transistors T1 to T7 and a single capacitor C1. Also, in addition to the input node where the power supply voltage VSS of a low level is input, the unit circuit 2 includes four input nodes 21 to 24 and one output node 29. In FIG. 6, the input node to which the set signal S is input is denoted by a reference sign of 21, the input node to which the clear signal CLR is input is denoted by a reference sign of 22, the input node to which the first clock signal CKA is input is denoted by a reference sign of 23, and the input node to which the second clock signal CKB is input is denoted by a reference sign of 24. Note that in the following, the wiring line configured to supply the power supply voltage VSS of a low level is referred to as a “VSS wiring line”.

A source terminal of the thin film transistor T1, a drain terminal of the thin film transistor T2, a gate terminal of the thin film transistor T4, a drain terminal of the thin film transistor T5, a gate terminal of the thin film transistor T6, and one end of the capacitor C1 are connected to one another. Note that, a region (the wiring lines) where these terminals are connected to one another is referred to as the “output control node”. The output control node is denoted by a reference sign of N1. A source terminal of the thin film transistor T3, a drain terminal of the thin film transistor T4, and a gate terminal of the thin film transistor T5 are connected to one another. Note that a region (the wiring lines) where these terminals are connected to one another is referred to as a “stabilization node”. The stabilization node is denoted by a reference sign of N2.

Both a gate terminal and a drain terminal of the thin film transistor T1 are connected to the input node 21 (in other words, the thin film transistor T1 is diode-connected), and the source terminal thereof is connected to the output control node N1. Note that in this example, the set signal is applied to the drain terminal of the thin film transistor T1, but the power supply voltage of a high level may be applied to the drain terminal of the thin film transistor T1. A gate terminal of the thin film transistor T2 is connected to the input node 22, the drain terminal thereof is connected to the output control node N1, and the source terminal thereof is connected to the VSS wiring line. A gate terminal and a drain terminal of the thin film transistor T3 are connected to the input node 24 (in other words, the thin film transistor T3 is diode-connected), and the source terminal thereof is connected to the stabilization node N2. The gate terminal of the thin film transistor T4 is connected to the output control node N1, the drain terminal thereof is connected to the stabilization node N2, and a source terminal thereof is connected to the VSS wiring line. The gate terminal of the thin film transistor T5 is connected to the stabilization node N2, the drain terminal thereof is connected to the output control node N1, and the source terminal thereof is connected to the VSS wiring line. The gate terminal of the thin film transistor T6 is connected to the output control node N1, a drain terminal thereof is connected to the input node 23, and a source terminal thereof is connected to the output node 29. A gate terminal of the thin film transistor T7 is connected to the input node 24, a drain terminal thereof is connected to the output node 29, and a source terminal thereof is connected to the VSS wiring line. The capacitor C1 is connected to the output control node N1 at one end and is connected to the output node 29 at the other end.

Note that according to the present embodiment, the set transistor is achieved by the thin film transistor T1, the initialization transistor is achieved by the thin film transistor T2, and the output control transistor is achieved by the thin film transistor T6. Additionally, the configuration of the unit circuit 2 illustrated in FIG. 6 is merely an example, and the disclosure is not limited thereto.

### 1.2.2 Operation

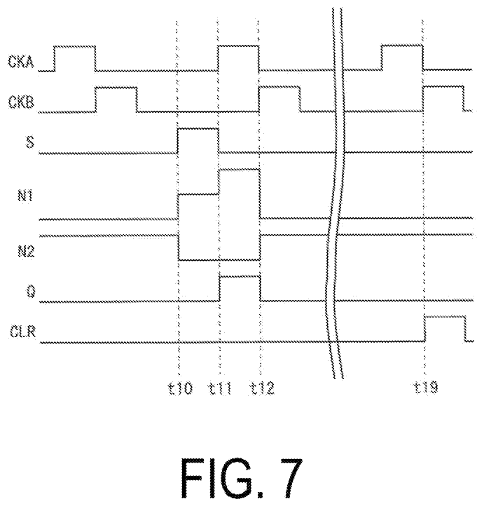

An operation of the unit circuit 2 in a normal case will be described with reference to FIG. 7. For a period before a point of time t10, a voltage of the output control node N1 is maintained at the low level, a voltage of the stabilization node N2 is maintained at the high level, and the output signal Q is maintained at the low level.

At the point of time t10, the set signal S changes from the low level to the high level. Since the thin film transistor T1 is diode-connected as illustrated in FIG. 6, the pulse of the set signal S sets the thin film transistor T1 to the on state, and the capacitor C1 is charged. Thus, the voltage of the output control node N1 changes from the low level to the high level, and the thin film transistor T6 is set to the on state. However, in a period from a point of time t10 to a point of time t11, the first clock signal CKA is at the low level, and thus, the output signal Q is maintained at the low level. Moreover, the voltage of the output control node N1 changes from the low level to the high level, and the thin film transistor T4 is set to the on state. This causes the voltage of the stabilization node N2 to be at the low level.

At the point of time t11, the first clock signal CKA changes from the low level to the high level. At this time, since the thin film transistor T6 is in the on state, a voltage of the output node 29 rises along with the rise of a voltage of the input node 23. Here, since the capacitor C1 is provided between the output control node N1 and the output node 29 as illustrated in FIG. 6, a voltage of the output control node N1 rises along with the rise of a voltage of the output node 29 (the output control node N1 is brought into a boost state). As a result, a large voltage is applied to the gate terminal of the thin film transistor T6, and a voltage of the output signal Q rises to a level sufficient to cause the gate bus line GL connected to the output node 29 to be in the selected state.

At a point of time t12, the first clock signal CKA changes from the high level to the low level. As a result, the voltage of the output node 29 (the voltage of the output signal Q) drops as the voltage of the input node 23 drops. As the voltage of the output node 29 drops, the voltage of the output control node N1 also drops via the capacitor C1. Additionally, at the point of time t12, the second clock signal CKB changes from the low level to the high level. This sets the thin film transistor T7 and the thin film transistor T3 to the on state. Since the thin film transistor T7 is set to the on state, the voltage of the output node 29 (the voltage of the output signal Q) is set to the low level. Since the thin film transistor T3 turns to the on state, the voltage of the stabilization node N2 changes from the low level to the high level, and the thin film transistor T5 is set to the on state. As a result, the voltage of the output control node N1 is set to the low level.

Thereafter, the clear signal CLR changes from the low level to the high level at a point of time t19 shortly before the end of the vertical scanning period. Thus, the thin film transistor T2 is set to the on state. As a result, even when the output control node N1 is affected by noise or the like, the voltage of the output control node N1 is reliably drawn to the low level.

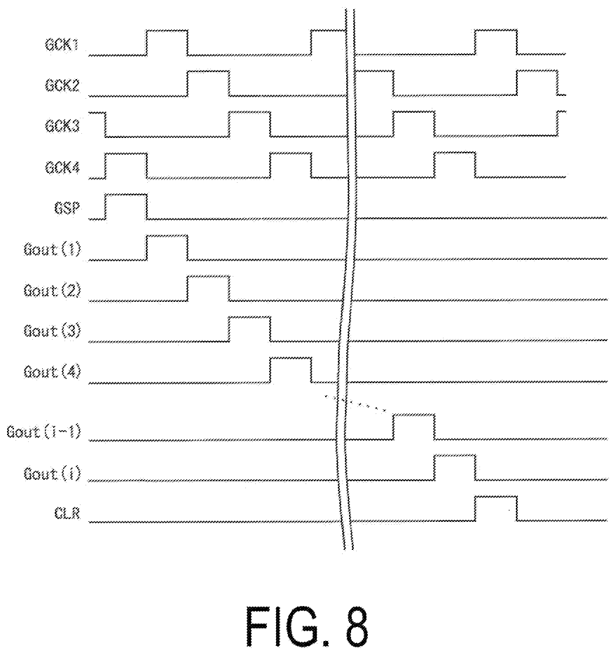

FIG. 8 is a signal waveform diagram for describing an overall operation of the gate driver 200. The operation as described above is performed in each unit circuit 2 in the shift register 210. Under the preconditions as described above, when a pulse of the gate start pulse signal GSP is applied to the unit circuit 2(1) at the first stage and the unit circuit 2(2) at the second stage after the start of each vertical scanning period, a shift pulse included in the output signal Q of each of the unit circuits 2 is transferred to the rear stage side (that is, a shift operation is performed) on the basis of clock operations of the first gate clock signal to the fourth gate clock signal GCK1 to GCK4. Then, in response to the transfer of the shift pulse, the output signals Q from the unit circuit 2(1) at the first stage to the unit circuit 2(i) at the i-th stage are sequentially set to the high level. As a result, as illustrated in FIG. 8, the scanning signals Gout(1) to Gout(i) that are sequentially set to the high level for a predetermined period are applied to the gate bus lines GL(1) to GL(i) in the display portion 400. In other words, i number of gate bus lines GL(1) to GL(i) are sequentially set to the selected state. After the gate bus line GL(i) of the i-th row becomes in the selected state, the pulse of the clear signal CLR is applied to all the unit circuits 2(1) to 2(i). As a result, the states of all the unit circuits 2(1) to 2(i) are initialized.

1.3 Configuration that Prevents Generation of Overcurrent

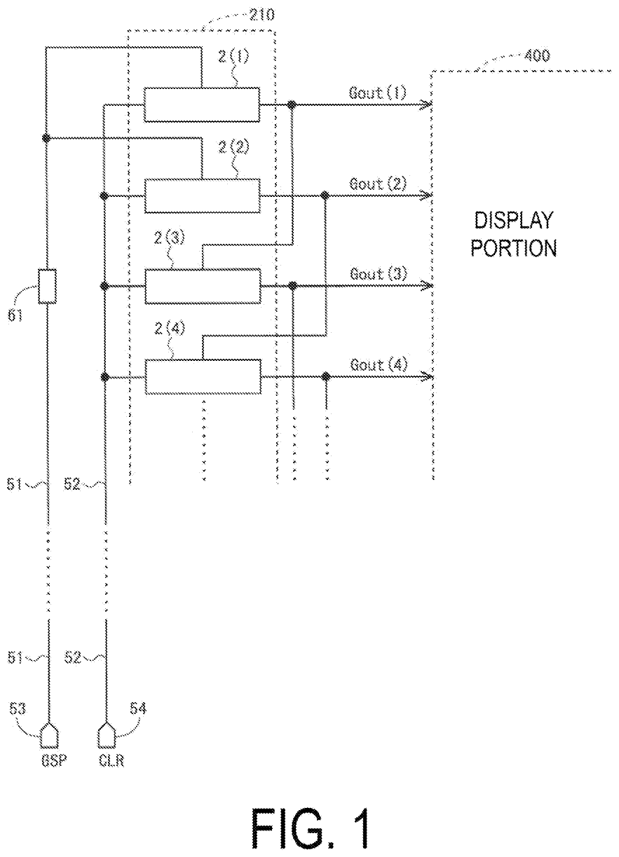

A configuration that prevents the generation of an overcurrent in the gate driver 200 that is a GDM circuit will be described with reference to FIG. 1. As described above, the gate driver 200 is formed directly on the TFT array substrate. The gate start pulse signal GSP is applied to an input terminal 53 on the TFT array substrate via the FPC from the timing control circuit 100 provided on the printed circuit board, for example. Similarly, the clear signal CLR is applied to an input terminal 54 on the TFT array substrate via the FPC from the timing control circuit 100 provided on the printed circuit board, for example. The input terminal 53 and the unit circuits 2(1) and 2(2) are connected by a wiring line denoted by a reference sign of 51 in FIG. 1 (hereinafter, for the sake of convenience, referred to as a “GSP signal wiring line”). The input terminal 54 and the unit circuits 2(1) to 2(i) are connected by a wiring line denoted by a reference sign of 52 in FIG. 1 (hereinafter, for the sake of convenience, referred to as a “CLR signal wiring line”). Note that the first control signal wiring line is achieved by the GSP signal wiring line, and the second control signal wiring line is achieved by the CLR signal wiring line.

As described above, the gate start pulse signal GSP is supplied from the timing control circuit 100 to the gate driver 200 through the GSP signal wiring line 51 disposed on the TFT array substrate, and the clear signal CLR is supplied from the timing control circuit 100 to the gate driver 200 through the CLR signal wiring line 52 disposed on the TFT array substrate.

Here, in the present embodiment, as a constituent element that prevents the generation of an overcurrent in the gate driver 200, a resistor 61 is provided on the GSP signal wiring line 51 as illustrated in FIG. 1. Note that in the example illustrated in FIG. 1, only one resistor 61 is provided, but no such limitation is intended, and a plurality of resistors 61 may be provided on the GSP signal wiring line 51.

In the configuration described above, when both the gate start pulse signal GSP and the clear signal CLR are at the high level due to the malfunction of the timing control circuit 100, the occurrence of ESD, or the like, both the thin film transistor T1 and the thin film transistor T2 become the on state in the unit circuit 2(1) at the first stage and the unit circuit 2(2) at the second stage. Due to this, a through current flowing through the thin film transistor T1 and the thin film transistor T2 is generated. However, since the resistor 61 is provided on the GSP signal wiring line 51, a significant increase in the current value of the through current is prevented. That is, the generation of an overcurrent is prevented.

### 1.4 Effects

According to the present embodiment, in the unit circuit 2 constituting the GDM circuit, the thin film transistor T1 having the gate terminal applied with the gate start pulse signal GSP and the thin film transistor T2 having the gate terminal applied with the clear signal CLR are connected in series. The timing control circuit 100 controls the waveform of the GDM control signal in such a manner that the gate start pulse signal GSP is maintained at the high level only for a part of the period immediately after the start of each vertical scanning period, and the clear signal CLR is maintained at the high level only for a part of the period near the end of each vertical scanning period. In the configuration described above, the resistor 61 is provided on the GSP signal wiring line 51 configured to transmit the gate start pulse signal GSP from the input terminal 53 (see FIG. 1) on the TFT array substrate to the GDM circuit (gate driver 200). Thus, even when both the gate start pulse signal GSP and the clear signal CLR are at the high level due to the occurrence of malfunction or ESD, the current value of the through current flowing through the thin film transistors T1 and T2 is prevented from becoming significantly large. In this way, the generation of an overcurrent in the GDM circuit is prevented. As described above, according to the present embodiment, a liquid crystal display device in which the generation of an overcurrent in the GDM circuit due to malfunction or ESD can be prevented is achieved.

### 1.5 Modification

In the first embodiment described above, the resistor 61 is provided on the GSP signal wiring line 51 to prevent the generation of an overcurrent in the GDM circuit. However, instead of this, a wiring line resistance of the GSP signal wiring line 51 may be increased to reduce the current value of the through current. For example, the wiring line resistance of the GSP signal wiring line 51 may be greater than a wiring line resistance of the clock signal wiring lines configured to transmit the gate clock signal GCK. To achieve this, for example, the GSP signal wiring line 51 is formed of a material having resistivity greater than that of the clock signal wiring lines. Examples of the material having great resistivity that forms the GSP signal wiring line 51 include indium tin oxide (ITO).

### 2. Second Embodiment

A second embodiment will be described below. An overall configuration, and a configuration and an operation of the gate driver 200 are similar to those of the first embodiment, and thus, the description thereof will be omitted (see FIGS. 2 to 8).

2.1 Configuration that Prevents Generation of Overcurrent

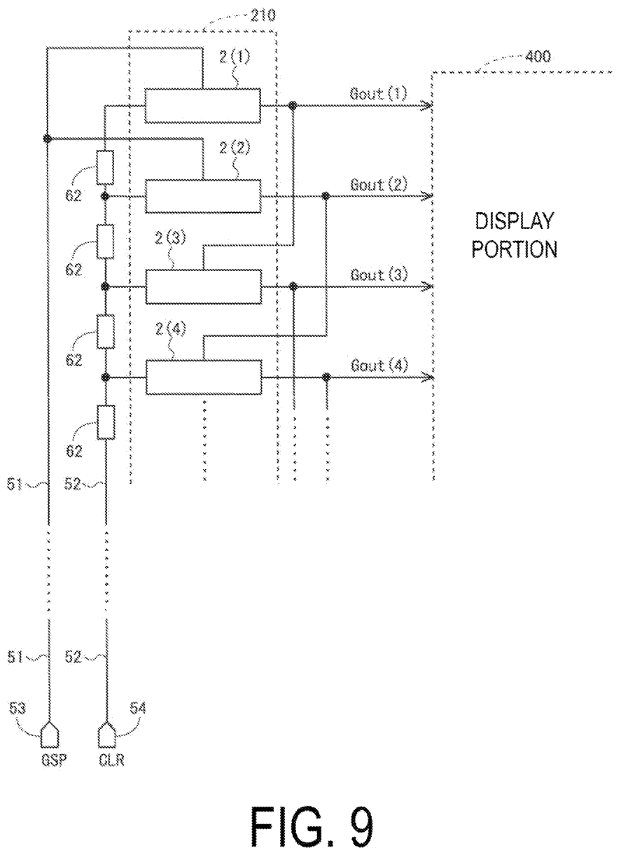

In the present embodiment, resistors 62 are provided on the CLR signal wiring line 52 as illustrated in FIG. 9 as constituent elements that prevent the generation of an overcurrent in the gate driver 200 serving as the GDM circuit. Note that in the example illustrated in FIG. 9, a plurality of resistors 62 are provided, but no such limitation is intended, and for example, only one resistor 62 may be provided near the input terminal 54 for the clear signal. Further, similarly to a modification of the first embodiment described above, a wiring line resistance of the CLR signal wiring line 52 may be greater than the wiring line resistance of the clock signal wiring lines by using a material having relatively great resistivity such as indium tin oxide for a material of the CLR signal wiring line 52.

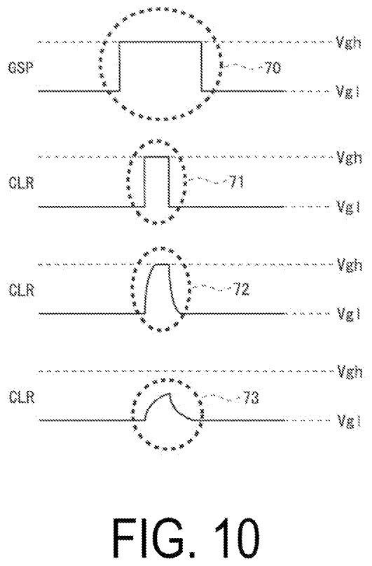

Next, a reason why the generation of an overcurrent is prevented by providing the resistors 62 on the CLR signal wiring line 52 will be described with reference to FIG. 10. It is assumed that the waveform of the clear signal CLR near the input terminal 54 is changed as indicated by a portion denoted by a reference sign of 71 due to instantaneous noise when the pulse of the gate start pulse signal GSP is generated as indicated in a portion denoted by a reference sign of 70. At this time, when the wiring line resistance of the CLR signal wiring line 52 is small, no significant delay occurs in the waveform of the clear signal CLR. Accordingly, the waveform of the clear signal CLR near the gate terminal of the thin film transistor T2 in the unit circuit 2 changes, for example, as indicated by a portion denoted by a reference sign of 72. In this case, when the thin film transistor T1 is in the on state, the thin film transistor T2 is also in the on state, and thus, an overcurrent is generated. In contrast, when the resistor 62 is provided on the CLR signal wiring line 52, a large delay occurs in the waveform of the clear signal CLR. Accordingly, the waveform of the clear signal CLR near the gate terminal of the thin film transistor T2 in the unit circuit 2 changes, for example, as indicated by a portion denoted by a reference sign of 73. In this case, the thin film transistor T2 does not become the on state or even when the thin film transistor T2 is assumed to be in the on state, the period thereof is very short. Thus, the generation of an overcurrent is prevented.

### 2.2 Effects

According to the present embodiment, in the unit circuit 2 constituting the GDM circuit, the thin film transistor T1 having the gate terminal applied with the gate start pulse signal GSP and the thin film transistor T2 having the gate terminal applied with the clear signal CLR are connected in series. The timing control circuit 100 controls the waveform of the GDM control signal in such a manner that the gate start pulse signal GSP is maintained at the high level only for a part of the period immediately after the start of each vertical scanning period, and the clear signal CLR is maintained at the high level only for a part of the period near the end of each vertical scanning period. In the configuration described above, the resistors 62 are provided on the CLR signal wiring line 52 that transmits the clear signal CLR from the input terminal 54 (see FIG. 1) on the TFT array substrate to the GDM circuit (gate driver 200). Thus, even when both the gate start pulse signal GSP and the clear signal CLR are at the high level due to the occurrence of malfunction or ESD, the current value of the through current flowing through the thin film transistors T1 and T2 is prevented from becoming significantly large. In this way, the generation of an overcurrent in the GDM circuit is prevented. As described above, according to the present embodiment, a liquid crystal display device in which the generation of an overcurrent in the GDM circuit due to malfunction or ESD can be prevented is achieved in a similar manner to that in the first embodiment.

### 3. Third Embodiment

A third embodiment will be described below. An overall configuration, and a configuration and an operation of the gate driver 200 are similar to those of the first embodiment, and thus, the description thereof will be omitted (see FIGS. 2 to 8).

3.1 Configuration that Prevents Generation of Overcurrent

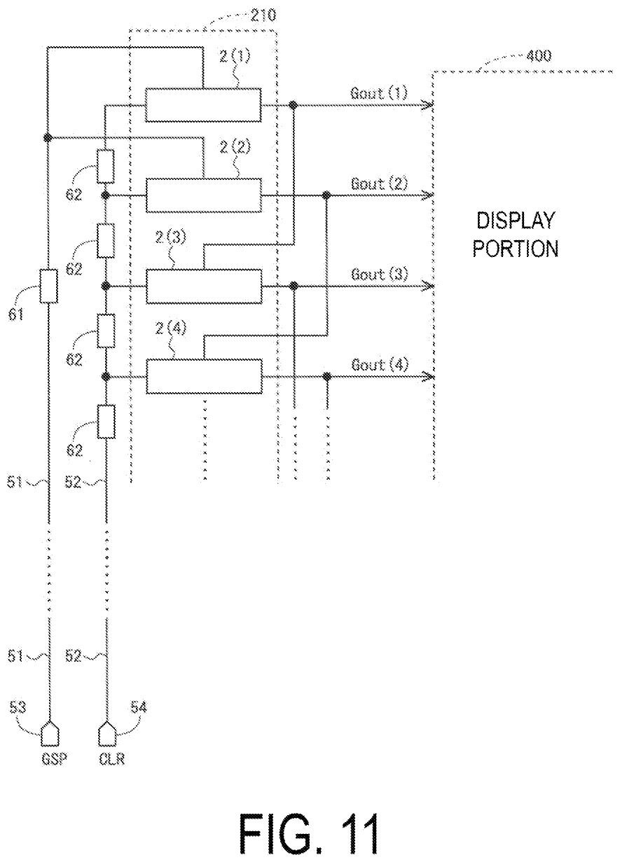

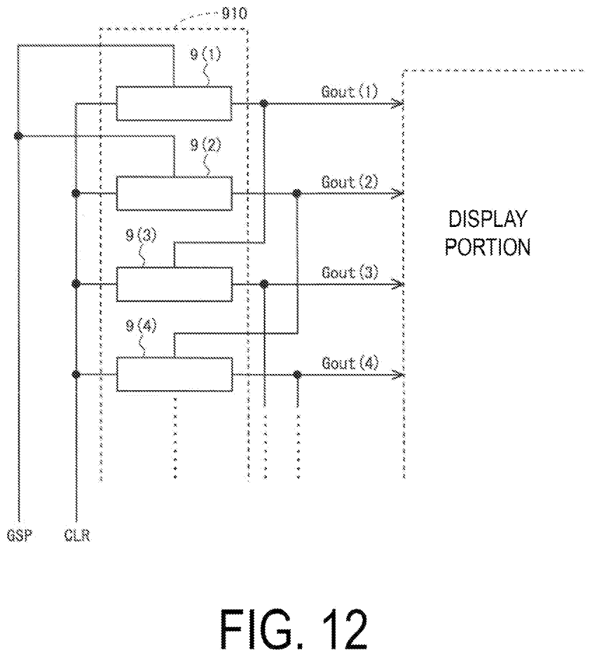

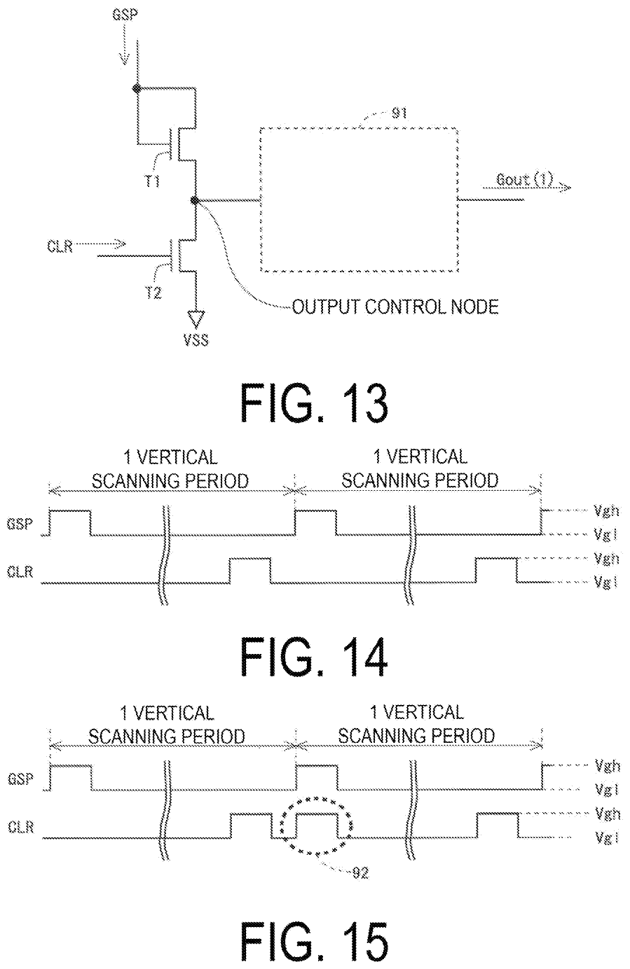

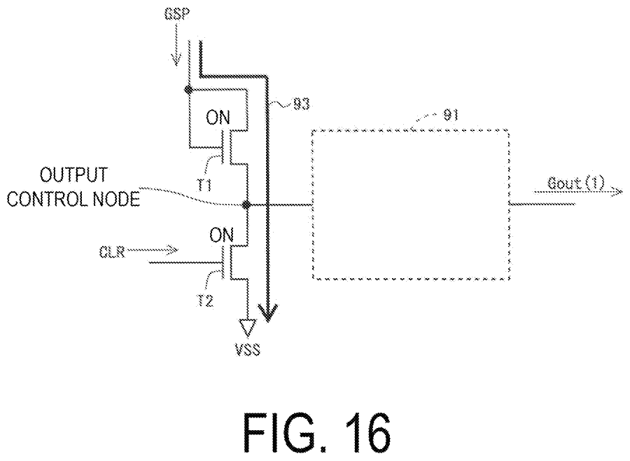

In the present embodiment, as illustrated in FIG. 11, the resistor 61 is provided on the GSP signal wiring line 51 in a similar manner to that in the first embodiment described above, and the resistors 62 are provided on the CLR signal wiring line 52 in a similar manner to that in the second embodiment described above. Note that the wiring line resistances of the GSP signal wiring line 51 and the CLR signal wiring line 52 may be greater than the wiring line resistance of the clock signal wiring lines by using a material having relatively great resistivity such as indium tin oxide for materials of the GSP signal wiring line 51 and the CLR signal wiring line 52.

### 3.2 Effects

According to the present embodiment, both the GSP signal wiring line 51 and the CLR signal wiring line 52 are provided with resistors, so when both the gate start pulse signal GSP and the clear signal CLR are at the high level due to the occurrence of malfunction or ESD, the current value of the through current flowing through the thin film transistors T1 and T2 in the unit circuit 2 can be effectively reduced. Accordingly, the generation of an overcurrent in the GDM circuit is effectively prevented. As described above, according to the present embodiment, a liquid crystal display device in which the generation of an overcurrent in the GDM circuit due to malfunction or ESD can be prevented is achieved.

### 4. Others

Although the disclosure has been described in detail above, the above description is exemplary in all respects and is not limiting. It is understood that numerous other modifications or variations can be made without departing from the scope of the disclosure. For example, in each embodiment, the liquid crystal display device has been described as an example, but the disclosure can also be applied to other display devices such as an organic EL display device.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. A display device comprising:
a display portion including a plurality of scanning signal lines;
a scanning signal line drive circuit configured to drive the plurality of scanning signal lines; and
a timing control circuit configured to generate a first control signal and a second control signal configured to control an operation of the scanning signal line drive circuit,
wherein the plurality of scanning signal lines and the scanning signal line drive circuit are formed on a panel substrate that is the same as a panel substrate configuring the display portion,
the timing control circuit generates the first control signal and the second control signal in such a manner that at least one of the first control signal and the second control signal is at an off level at any point of time,
the first control signal and the second control signal are each supplied to the scanning signal line drive circuit from the timing control circuit through a first control signal wiring line and a second control signal wiring line disposed on the panel substrate, and
a resistor is provided on at least one of the first control signal wiring line and the second control signal wiring line.

2. The display device according to claim 1,
wherein the scanning signal line drive circuit is configured of a shift register including a plurality of unit circuits corresponding one-to-one to the plurality of scanning signal lines,
the first control signal is a vertical scanning start signal to be applied to a unit circuit at least at a first stage among the plurality of unit circuits to allow vertical scanning in which the plurality of scanning signal lines are sequentially brought into a selected state to start, and
the second control signal is a clear signal to be applied to the plurality of unit circuits to allow a state of the plurality of unit circuits to be initialized after an end of the vertical scanning.

3. The display device according to claim 2,
wherein the resistor is provided only on the first control signal wiring line.

4. The display device according to claim 2,
wherein the resistor is provided only on the second control signal wiring line.

5. The display device according to claim 2,
wherein the resistor is provided on each of the first control signal wiring line and the second control signal wiring line.

6. The display device according to claim 2,
wherein a plurality of clock signals are further supplied from the timing control circuit to the scanning signal line drive circuit,
each of the plurality of unit circuits includes
an output node connected to a corresponding scanning signal line among the plurality of the scanning signal lines,
an output control transistor including a control terminal, a first conduction terminal to be applied with one of the plurality of clock signals, and a second conduction terminal connected to the output node,
an output control node connected to the control terminal of the output control transistor,
a set transistor including a control terminal to be applied with a set signal, a first conduction terminal to be applied with the set signal or a power supply voltage of an on level, and a second conduction terminal connected to the output control node, and
an initialization transistor including a control terminal connected to the second control signal wiring line, a first conduction terminal connected to the output control node, and a second conduction terminal to be applied with a power supply voltage of an off level, and
the unit circuit at least at the first stage among the plurality of unit circuits is applied with the vertical scanning start signal as the set signal.

7. A display device comprising:
a display portion including a plurality of scanning signal lines;
a scanning signal line drive circuit configured to drive the plurality of scanning signal lines; and
a timing control circuit configured to generate a first control signal, a second control signal, and a plurality of clock signals configured to control an operation of the scanning signal line drive circuit,
wherein the plurality of scanning signal lines and the scanning signal line drive circuit are formed on a panel substrate that is the same as a panel substrate configuring the display portion,
the timing control circuit generates the first control signal and the second control signal in such a manner that at least one of the first control signal and the second control signal is at an off level at any point of time,
the first control signal, the second control signal, and the plurality of clock signals are each supplied to the scanning signal line drive circuit from the timing control circuit through a first control signal wiring line, a second control signal wiring line, and a plurality of clock signal wiring lines disposed on the panel substrate, and
a wiring line resistance of at least one of the first control signal wiring line and the second control signal wiring line is greater than a wiring line resistance of the plurality of clock signal wiring lines.

8. The display device according to claim 7,
wherein the scanning signal line drive circuit is configured of a shift register including a plurality of unit circuits corresponding one-to-one to the plurality of scanning signal lines,
the first control signal is a vertical scanning start signal to be applied to a unit circuit at least at a first stage among the plurality of unit circuits to allow vertical scanning in which the plurality of scanning signal lines are sequentially brought into a selected state to start, and
the second control signal is a clear signal to be applied to the plurality of unit circuits to allow a state of the plurality of unit circuits to be initialized after an end of the vertical scanning.

9. The display device according to claim 8,
wherein each of the plurality of unit circuits includes
an output node connected to a corresponding scanning signal line among the plurality of the scanning signal lines,
an output control transistor including a control terminal, a first conduction terminal to be applied with one of the plurality of clock signals, and a second conduction terminal connected to the output node,
an output control node connected to the control terminal of the output control transistor,
a set transistor including a control terminal to be applied with a set signal, a first conduction terminal to be applied with the set signal or a power supply voltage of an on level, and a second conduction terminal connected to the output control node, and
an initialization transistor including a control terminal connected to the second control signal wiring line, a first conduction terminal connected to the output control node, and a second conduction terminal to be applied with a power supply voltage of an off level, and
the unit circuit at least at a first stage among the plurality of unit circuits is applied with the vertical scanning start signal as the set signal.

10. The display device according to claim 7,
wherein the at least one of the first control signal wiring line and the second control signal wiring line is formed of a material having resistivity greater than resistivity of the plurality of clock signal wiring lines.

11. The display device according to claim 7,
wherein a material of the at least one of the first control signal wiring line and the second control signal wiring line is indium tin oxide.
